(19) United States
(12) Patent Application Publication
(10) Pub. No.: US 2020/0028047 A1
(43) Pub. Date: Jan. 23, 2020

(54) LIGHT EMITTING DIODE ARRAY PACKAGE STRUCTURE WITH HIGH THERMAL CONDUCTIVITY

(71) Applicant: NATIONAL TAIWAN UNIVERSITY OF SCIENCE AND TECHNOLOGY, Taipei (TW)

(72) Inventor: JUNG-CHIEH SU, Taipei (TW)

(73) Assignee: NATIONAL TAIWAN UNIVERSITY OF SCIENCE AND TECHNOLOGY, Taipei (TW)

(21) Appl. No.: 16/508,537

(22) Filed: Jul. 11, 2019

(30) Foreign Application Priority Data
Jul. 20, 2018 (TW) 107209892
May 22, 2019 (TW) 108117755

(51) Int. Cl. H01L 33/64; H01L 25/075; H01L 33/50; H01L 33/56; H01L 33/60; H01L 33/62

(52) U.S. Cl. CPC H01L 33/641; H01L 25/0753; H01L 33/502; H01L 33/644; H01L 33/60; H01L 33/62; H01L 33/56

(57) ABSTRACT

A light emitting diode (LED) array package structure includes a package substrate, a LED array, a high thermal conductive color conversion layer and a transparent ceramic substrate. The high thermal conductive color conversion layer includes a mixture of transparent optical resin, phosphor powder and transparent ceramic filler, and is directly dispensed on the LED array. The transparent ceramic substrate contacts directly the high thermal conductive color conversion layer. A portion of the transparent ceramic filler contacts the package substrate while another portion contacts the transparent ceramic substrate. The conduction and radiation heat generated by the high thermal conductive color conversion layer, and the conductive heating caused by the LED chips, both can be removed through either the package substrate or the transparent ceramic substrate, thereby improving the white light output power and being suitable for implementing with polymeric optical components to reduce glare and enhance luminous efficiency.

### BACKGROUND OF THE INVENTION

### (1) Field of the Invention

The present invention relates to a package structure of light emitting diode, in particular, to a light emitting diode array package structure capable of solving high temperature and glare problems.

### (2) Description of the Prior Art

If conventional light-emitting diode lighting devices use white light-emitting diode light sources with high-brightness greater than 1000 lumens, the light sources usually require the use of a blue light emitting diode array packaged in the form of a two-dimensional array, and the blue light emitting diode array to be covered with a yellow phosphor resin layer, for converting the color of the lighting.

As shown in FIG. 1, a conventional chip-on-board package structure 100 of a light emitting diode array is disposed on a heat sink 300. Hereinafter, the term “chip-on-board” is simply referred to as “COB”, and the term “light emitting diode” is simply referred to as “LED”. The COB package structure 100 includes a package substrate 110, a plurality of blue light emitting diode (LED) chips 122, and a yellow phosphor resin layer 130. The package substrate 110 includes a circuit layer 112 and an insulating layer 114, and the insulating layer 114 is located on the circuit layer 112. Each two adjacent blue LED chips 122 are connected by a bonding wire 124 or connected by flip-chip bonding, and arranged in a two-dimensional blue LED array 120. The blue LED array 120 is directly mounted on the insulating layer 114 of the package substrate 110 and electrically connected to the circuit layer 112. The yellow phosphor resin layer 130 is a silicon resin layer containing dispersed phosphor powder, which are directly over and around each of the blue LED chips 122. The heat flow path when the blue LED array 120 emits light is as shown by the arrow of FIG. 1. A portion of the heat is conducted directly upward to the yellow phosphor resin layer 130; another portion of the heat is removed downward through the package substrate 110 to the heat sink 300.

In the COB package structure 100, a portion of the blue light emitted by the blue LED chip 122 is converted into a yellow light having a longer wavelength by the yellow phosphor resin layer 130, and another portion of the unconverted blue light is mixed with the yellow light through the yellow phosphor resin layer 130 to form a white light. The temperature of white light LED is generally affected by two factors: one is that the yellow phosphor resin layer 130 has its own temperature rise due to the wavelength conversion effect; the other is that the blue LED chip 122 heats the surrounding yellow phosphor resin layer 130.

The first factor is that the color conversion efficiency of the yellow phosphor resin layer 130 is not 100%, so heating problems may occur when the blue light is converted into yellow light via the yellow phosphor resin layer 130, and the color conversion efficiency becomes lower when the temperature of the yellow phosphor resin layer 130 becomes higher. This heating problem also affects the amount of light output from the blue LED chip 122. In the conventional COB package structure 100, the heat generated by the yellow phosphor resin layer 130 during color conversion is also propagated to the heat sink 300 for heat dissipation.

The second factor is that since the blue LED chip 122 is packaged inside the yellow phosphor resin layer 130, the thickness of the yellow phosphor resin layer 130 is about several hundred micrometers, and the thermal property of the yellow phosphor resin layer 130 is with a relatively low thermal conductivity. The heating of the blue LED chip 122 also easily causes a temperature rise and a decrease in luminous efficiency of the yellow phosphor resin layer 130. The temperature of the surface of the yellow phosphor resin layer 130 is greater than 150° C. when inputting with 10 W power. In order to implement a secondary optical component near the surface of the yellow phosphor resin layer 130, a metal or a glass optical components that can withstand high temperatures is required, while a secondary optical component made of polymeric optical materials cannot be used.

In view of this, if the excess COB LED surface temperature issue affecting the white light output can be solved under the premise of maintaining the small-sized package structure, and if the polymeric secondary optical component that could not be used originally can be used to improve white light brightness and eliminate glare, the quality of white light output may be improved and the advantage of low cost may be obtained.

### SUMMARY OF THE INVENTION

One object of the present invention is to provide a light emitting diode array package structure with high thermal conductivity, which may meet the requirements of small size, high luminance, anti-glare, heat dissipation and cost reduction.

In order to achieve the aforementioned object, the present invention provides a LED array package structure with high thermal conductivity suitable for being mounted on a heat sink including a package substrate, a LED array, a high thermal conductive color conversion layer and a transparent ceramic substrate. The package substrate is disposed on the heat sink and includes a circuit layer and an insulating layer, wherein the insulating layer is located on the circuit layer. The LED array includes a plurality of LED chips arranged in an array form, wherein each of the LED chips is directly mounted on the insulating layer of the package substrate and electrically connected to the circuit layer. The high thermal conductive color conversion layer is directly dispensed on the LED array and the package substrate. The high thermal conductive color conversion layer includes a transparent optical resin, a phosphor powder and a transparent ceramic filler, wherein the phosphor powder and the transparent ceramic filler are mixed into the transparent optical resin, and a portion of transparent ceramic filler is in direct contact with the package substrate to form a thermal conduction path. The transparent ceramic substrate directly covers and contacts an upper surface of the high thermal conductive color conversion layer, and contacts another portion of the transparent ceramic filler to form another thermal conduction path.

In an embodiment, the transparent ceramic filler is in the form of a powder having a particle size of nano-scale, named a nano-scale transparent ceramic filler. The weight percentage of the nano-scale transparent ceramic filler relative to the transparent optical resin is, for example, greater than 0% and less than or equal to 10%, or greater than 0% and less than or equal to 20%. The material of both the nano-scale transparent ceramic filler and the transparent ceramic substrate is selected from a group consisting of aluminum nitride (AlN) and aluminium oxide (Al₂O₃), magnesium aluminate spinel (MgAl₂O₄), aluminum oxynitride (AlON), quartz and glass. Preferably, the material of the nano-scale transparent ceramic filler is the same as that of the transparent ceramic substrate.

In an embodiment, the LED array package structure with high thermal conductivity includes a first thermal conductive frame, a reflective polarizer and a second thermal conductive frame. The first thermal conductive frame connects a periphery of the transparent ceramic substrate to the heat sink. The reflective polarizer is disposed on the transparent ceramic substrate. There is an air gap formed between the reflective polarizer and the transparent ceramic substrate. The second thermal conductive frame connects a periphery of the reflective polarizer to the heat sink. The first thermal conductive frame and the second thermal conductive frame are each fixed to the heat sink with a high thermal conductivity screw.

According to the structure of the present invention, either radiant and conduction heat generated by the high thermal conductive color conversion layer itself during color conversion or the conductive heating of the high thermal conductivity color conversion layer by the blue LED chip array may be removed via the transparent ceramic substrate located thereon and its thermal conductive frame, or removed by conducting from the package substrate to the heat sink, so that the heat radiation reaching the space on the transparent ceramic substrate and the temperature of color conversion layer may be effectively reduced. Therefore, in the present invention, a reflective polarizer made of a polymeric material having a low thermal conductivity in addition to the glass substrate polarizer may be used on the top surface of the transparent ceramic substrate, so as to reduce cost, improve white light output efficiency and reduce glare.

### BRIEF DESCRIPTION OF THE DRAWINGS

FIG. 1 is the schematic view of a conventional COB package structure of a LED array.

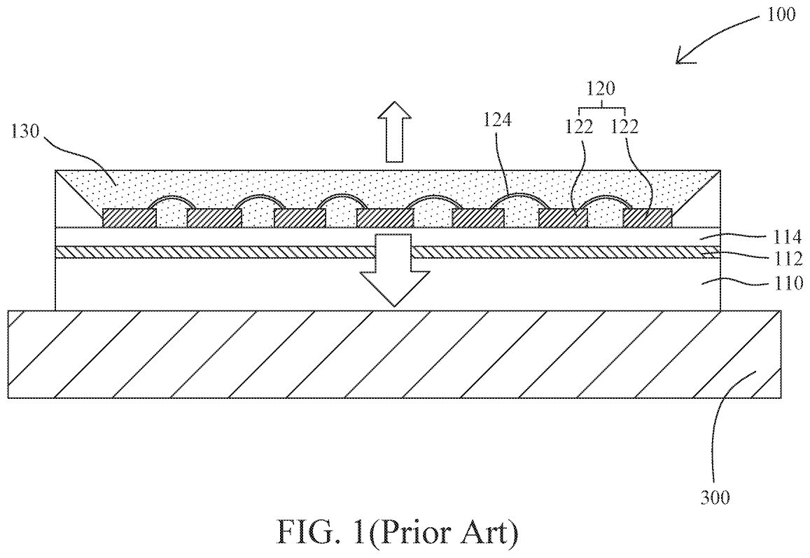

FIG. 2 is the schematic view of one embodiment for a LED array package structure with high thermal conductivity according to the present invention.

FIG. 2A is a diagram showing the surface temperature change curves and luminous flux for the high thermal conductive color conversion layer with and without a transparent ceramic substrate thereon in a 8-Watt chip-on-board light emitting diode package structure (referred to as a “8 W COB LED”) according to the present invention.

FIG. 3 is the schematic view of one embodiment for a LED array package structure with high thermal conductivity and low glare according to the present invention.

FIG. 4 is the schematic view of the direction of thermal conduction in one embodiment according to the present invention.

### DESCRIPTION OF THE PREFERRED EMBODIMENTS

In the following the details of a preferred embodiment accompanied by its corresponding drawings clearly explain the early statements on this invention and other technical contents, features, and functions. In this regard, the direction-related terms, such as “top,” “bottom,” “left,” “right,” “front,” “back,” etc., are used with reference to the orientations of the objects in the Figure(s) being considered. The components of the present invention can be positioned in a number of different orientations. As such, the direction-related terms are used for the purposes of illustration and by no means as restrictions to the present invention. On the other hand, the sizes of the objects in the schematic drawings may be overstated for the purpose of clarity. It is to be understood that other likely-employed embodiments or possible changes made in the structure of the present invention should not depart from the scope of the present invention. Also, it is to be understood that the phraseology and the terminology used herein are for the purpose of description and should not be regarded as limits to the present invention. The use of “including,” “comprising,” or “having” and variations thereof herein is meant to cover the items listed thereafter and equivalents thereof as well as additional items. Unless otherwise stated, the terms “connected,” “coupled,” and “mounted” and variations thereof herein are used in a broad sense and cover direct and indirect connections, couplings, and mountings. Similarly, the terms “facing,” “faces” and variations thereof herein are used in a broad sense and cover direct and indirect facing, and the term “adjacent to” and variations thereof herein is used in a broad sense and cover directly and indirectly “adjacent to”. Therefore, the description of “A” component facing “B” component herein may include the situations that “A” component facing “B” component directly or one or more additional components between “A” component and “B” component. Also, the description of “A” component “adjacent to” “B” component herein may include the situations that “A” component is directly “adjacent to” “B” component or one or more additional components between “A” component and “B” component. Accordingly, the drawings and the descriptions will be regarded as illustrative in nature, but not restrictive.

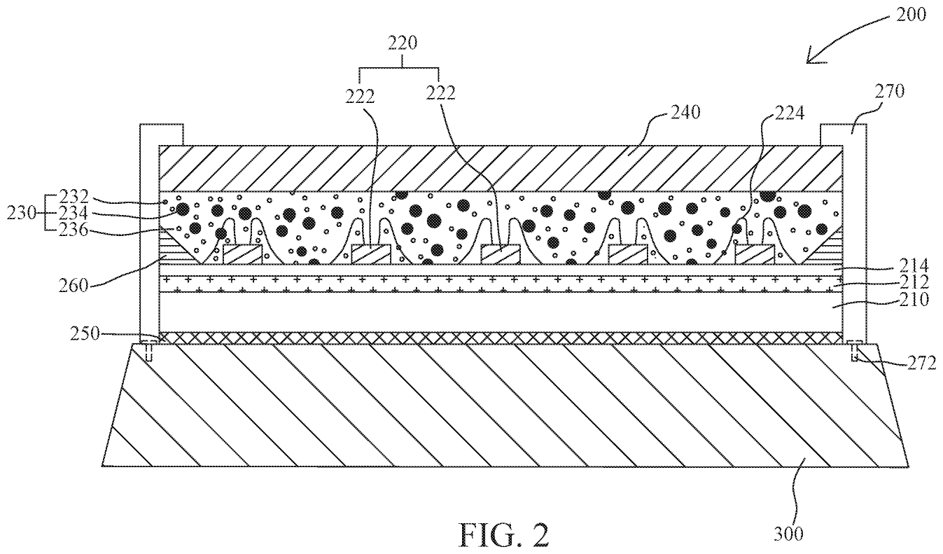

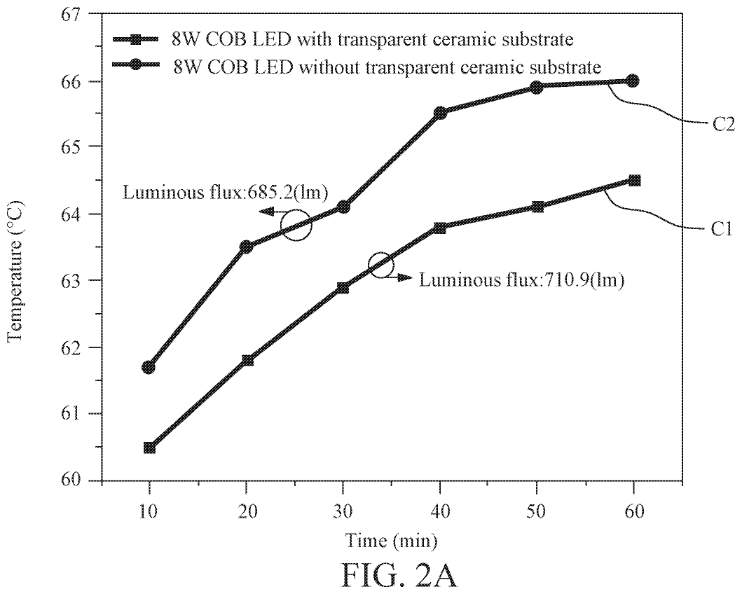

FIG. 2 is an embodiment of the present invention, a light emitting diode array package structure 200 (hereinafter referred to as a “LED array package structure 200”) with high thermal conductivity comprises a package substrate 210, a light emitting diode array 220 (hereinafter referred to as a “LED array 220”), a high thermal conductive color conversion layer 230, and a transparent ceramic substrate 240. The LED array 220 is directly mounted on the package substrate 210. In particular, in the present embodiment, a transparent ceramic filler 232 and a phosphor powder 234 are mixed into a transparent optical resin 236 to form a modified composite phosphor material. The modified composite phosphor material is coated on the blue LED array 220 to form a high thermal conductive color conversion layer 230. Then, a transparent ceramic substrate 240 is placed over the high thermal conductive color conversion layer 230 to absorb and insulate the radiation heat and conduction heat generated by the high thermal conductive color conversion layer 230 during the color conversion process. It should be noted that the present invention is different from the conventional “remote phosphor powder coating technology”. The “remote phosphor powder coating technology” refers to isolating the phosphor resin layer from the LED array, but the present invention is to fill directly the LED array 220 with the high thermal conductive color conversion layer 230 containing the phosphor powder 234.

An upper surface of the package substrate 210 is provided with a circuit layer 212 and an insulating layer 214. The circuit layer 212 is connected to an electrical signal source. The insulating layer 214 is located on the circuit layer 212. The LED array 220 includes a plurality of light emitting diode chips 222 (hereinafter referred to as “LED chips 222”) arranged in an array form, and each two adjacent LED chips 222 are connected by a bonding wire 224. Among which, each of the LED chips 222 is directly mounted on the insulating layer 214 of the package substrate 210 and electrically connected to the circuit layer 212. The high thermal conductive color conversion layer 230 directly covers the LED array 220, so that a part of the transparent ceramic filler 232 contacts the lower package substrate 210 for enhancing the downward thermal conduction effect, and another part of the transparent ceramic filler 232 contacts the upper transparent ceramic substrate 240 for enhancing the upward thermal conduction effect. The transparent ceramic substrate 240 directly covers and is in contact with the upper surface of the high thermal conductive color conversion layer 230 to absorb and insulate radiation heat and conduction heat. The enclosure adhesive 260 is disposed and surrounds the periphery of the LED array 220 for protecting the LED array 220 and fixing the high thermal conductive color conversion layer 230.

In addition, the LED array package structure 200 is disposed on a heat sink 300. In order to increase the heat conduction efficiency between the package substrate 210 and the heat sink 300, a thermal grease layer 250 is coated between the package substrate 210 and the heat sink 300 to quickly transfer heat out from the package substrate 210, so as to enhance the heat dissipation effect of the lower surface of the high thermal conductive color conversion layer 230 to the heat sink 300. Thus, the transparent ceramic filler 232, the package substrate 210, the thermal grease layer 250, and the heat sink 300 are connected to form a downward thermal conduction path.

The periphery of the transparent ceramic substrate 240 is fixed by a thermal conductive frame 270 made of a highly thermal conductive material, and the thermal conductive frame 270 is connected to the heat sink 300 to form another thermal conduction path for directly conducting the radiation heat and the conduction heat received by the transparent ceramic substrate 240 to the heat sink 300, thereby enhancing the heat dissipation effect. The thermal conductive frame 270 may provide for the transparent ceramic substrate 240 to directly dissipate heat to the heat sink 300 without passing through the package substrate 210 of the LED array 220.

In an embodiment, the LED array 220 uses an array formed by blue LED chips 222. The high thermal conductive color conversion layer 230 employs a silicon resin layer containing a mixture of yellow phosphor powder 234 and high thermal conductive nano-scale transparent ceramic filler 232. The characteristics and effects of the high thermal conductive color conversion layer 230 are as follows: (1) the refractive index is greater than that of the conventional transparent adhesive layer, so that the light extraction efficiency of the blue light may be increased, that is, the total reflection effect of the surface of the blue LED chip 222 is reduced; (2) the thermal conductivity coefficient is larger than that of the conventional phosphor resin layer, so that the high surface temperature generated by the wavelength conversion effect of the phosphor resin layer due to absorption of blue light may be reduced, and the heating effect of the blue LED chip 222 is reduced, so that the surface of the high thermal conductive color conversion layer 230 generates low surface temperature and its radiation heat is lower than the conventional phosphor resin layer.

In the high thermal conductive color conversion layer 230, the material of the nano-scale transparent ceramic filler 232 may be selected from aluminum nitride (AlN), aluminum oxide (Al₂O₃), magnesium aluminate spinel (MgAl₂O₄), aluminum oxynitride (AlON), or quartz and glass in powder or granule form, preferably aluminum nitride powder or aluminum oxynitride powder. The mixing ratio of the nano-scale transparent ceramic filler 232 relative to the transparent optical resin 236 is, for example, greater than 0% and less than or equal to 20% by weight, preferably greater than 0% and less than or equal to 10% by weight, such as 2%, 5% or 7%.

The transparent ceramic substrate 240 is mainly made of ceramics having high transparency to light and high thermal conductivity, for example, aluminum nitride (AlN), aluminum oxide (Al₂O₃), magnesium aluminum spinel (MgAl₂O₄), aluminum oxynitride (AlON), etc., or quartz and glass, but is not limited to these materials. In an embodiment, the transparent ceramic fillers 232 and the transparent ceramic substrate 240 may be made of the same material. For example, both use aluminum nitride materials, which may increase the thermal conductivity by using the same materials to get in touch with each other.

It should be noted that the structure of the present invention may produce an effect that is difficult for those skilled in the art to anticipate. In prior art, a good thermal management for the effect of temperature reduction is required to maintain the stable output luminance. Generally, a high thermal conductive paste, a cold plate, a heat pipe, a high heat dissipation package substrate such as copper or ceramics, or a forced convection cooling heat sink is used to greatly reduce the temperature of the LED package structure, and to reduce the occurrence of lumen depreciation. This will increase the cost of COB LED packaging. And the secondary optical component is unable to use in the COB LED package structure because the temperature on the surface of the COB LED package structure may be too high. However, the present invention not only greatly reduces the temperature of the LED array package structure 200 under low cost conditions, but also increases its luminance.

The conventional technique for adding other modified fillers to the phosphor resin layer is mostly to change the luminescent properties of the phosphor resin layer, e.g., adding transparent particulate such as polymethyl methacrylate (PMMA) to make the white light emitted by the LEDs more uniform. However, this approach generally dims the brightness of the LED package structure due to the light scattering. Further, placing a transparent substrate on the light source leads to the concern of reducing the luminance of the light. Under the concern that it is possible to sacrifice luminance, those skilled in the art generally do not want to place a transparent substrate over the phosphor powder layer mixed with the modified filler to increase the heat dissipation path. However, in the present invention, mixing the transparent ceramic filler 232 with the transparent optical resin 236 in a specific ratio with combination of the transparent ceramic substrate 240 may not greatly reduce the luminance of the LED array package structure 200 as expected, but may cause the luminance to increase and the surface temperature of the transparent ceramic substrate 240 to be lower after measurement as compared with the case where the transparent ceramic substrate 240 is not added.

With reference to the surface temperature measurement data of a 8-Watt chip-on-board light emitting diode package structure (referred to as a “8 W COB LED”) over time shown in FIG. 2A, curve C1 shows a surface temperature change curve when the transparent ceramic substrate 240 is added as shown in FIG. 2, and curve C2 is a curve showing the surface temperature of the high thermal conductive color conversion layer 230 after the transparent ceramic substrate 240 is removed from the structure of FIG. 2. Compared with the structure without the transparent ceramic substrate 240, the structure with the transparent ceramic substrate 240 has a lower surface temperature when the same light-emitting time is passed, but has a larger luminous flux. It will be apparent that the structure of the present invention may compensate for light scattering losses due to the transparent ceramic filler 232 and further reduce temperature.

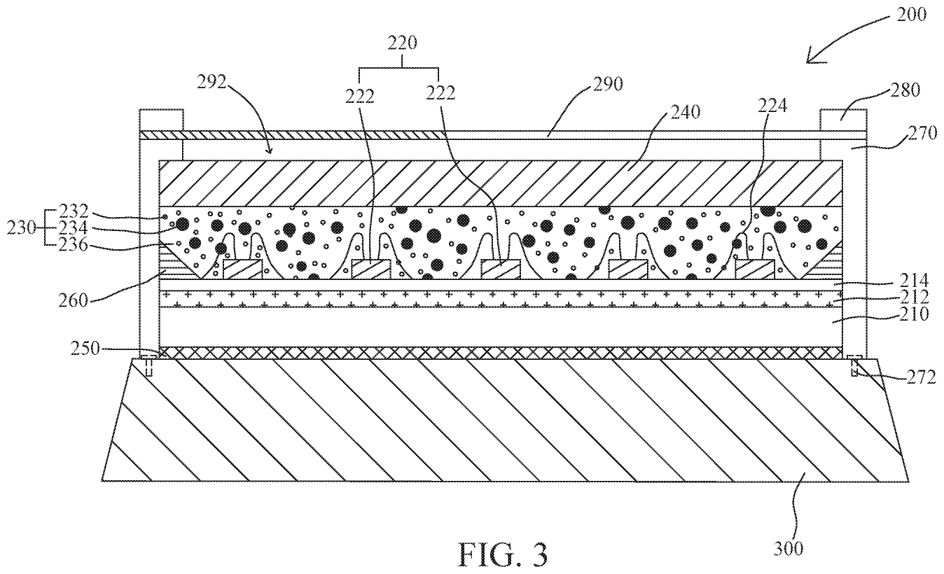

The reason is that the thermal quenching effect of the phosphor powder 234 causes the color conversion efficiency of the high thermal conductive color conversion layer 230 to be attenuated at high temperatures, and the luminous efficiency of the blue LED chip 222 to be decreased as the temperature of the high thermal conductive color conversion layer 230 increases. However, the structure of the present invention may quickly remove the heat generated by the high thermal conductive color conversion layer 230 and the blue LED chip 222 to improve the luminous efficiency of blue light and yellow light, thereby increasing the amount of light emitted from the high thermal conductive color conversion layer 230, so as to compensate for light scattering losses due to the transparent ceramic filler 232. Accordingly, the luminance of the air gap 292 on the transparent ceramic substrate 240 is still increased for the entire LED array package structure 200 as shown in FIG. 3.

FIG. 3 shows a polymer optical component, such as a polymeric reflective polarizer 290, mounted on the transparent ceramic substrate 240 of the embodiment shown in FIG. 2 with an air gap 292 therebetween. The polymeric reflective polarizer 290 is, for example, a nano-wire grid polarizer with a polymeric cellulose triacetate (referred to as “TAC”) substrate. The polymeric reflective polarizer 290 is used to polarize the generated unpolarized white light and reflect some portion of the blue light with the undesired polarization, so as to recycle these blue light by multiply reflecting through the transparent ceramic substrate 240 back into the high thermal conductive color conversion layer 230 for color conversion and polarization randomization repeatedly, so that the luminous efficiency of white light is increased and the excess blue light of the high color temperature can be reduced, thereby increasing white light output and increasing the polarization ratio of the output white light, which can be used for the lighting application of reducing glare.

The periphery of the polymeric reflective polarizer 290 is fixed by a thermal conductive frame 280, and connected to the heat sink 300 by the thermal conductive frame 280 to form another thermal conduction path, for directly conducting the radiation heat received by the polymeric reflective polarizer 290 to the heat sink 300. The above two thermal conductive frames 270 and 280 are all made of a metal material having a high thermal conductive coefficient, such as a copper, and are fixedly connected to the heat sink 300 by high thermal conductive screws 272. In the present embodiment, since the temperature and heat radiation generated on the surface of the high thermal conductive color conversion layer 230 is lower than the conventional fluorescent adhesive layer, and a thermal conduction path is provided by using the transparent ceramic substrate 240, the radiation heat may be effectively prevented from damaging the polymeric reflective polarizer 290 from the surface of the high thermal conductive color conversion layer 230 directly through the air gap 292.

Since the low-cost polymeric reflective polarizer 290 used may only resist heat of less than 100° C., the heat is radiated from the surface of the transparent ceramic substrate 240 to the polymeric reflective polarizer 290 via thermal radiation may be conducted to the heat sink 300 by fixing the thermal conductive frame 280 to the heat sink 300 with the high thermal conductive screw 272, so as to lower the temperature of the polymeric reflective polarizer 290.

In an embodiment, the contact interface between the package substrate 210 and the heat sink 300, the contact interface between the thermal conductive frame 270 and the transparent ceramic substrate 240, and the contact interface between the thermal conductive frame 280 and the polymeric reflective polarizer 290 may uniformly be coated with an appropriate amount of thermal paste for quickly conducting out the heat.

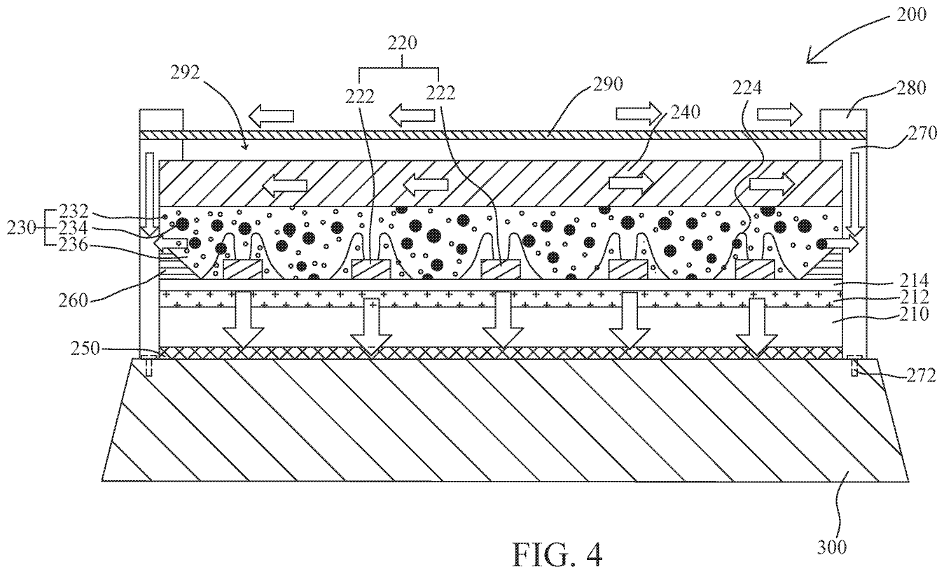

The arrow of FIG. 4 indicates the direction of thermal conduction in the LED array package structure 200 of the present invention. The LED array package structure 200 of the present embodiment has two heat sources: one is the heat generated by the blue LED chip 222 during the light emission process; the other is the radiant and conduction heat generated by the high thermal conductive color conversion layer 230 due to energy loss when converting the blue wavelength into the yellow wavelength.

For the thermal conduction of the first heat source, a portion of the heat generated by the blue LED chip 222 during the light emission process is removed by conducting downward through the package substrate 210 to the heat sink 300, and another portion is conducted upward.

For the thermal conduction of the second heat source, the radiant and conduction heat generated due to the energy loss of the high thermal conductive color conversion layer 230 during the conversion of the wavelength of the light are directly conducted to the thermal conductive frame 270 via the transparent ceramic substrate 240, then conducted to the heat sink 300 by the thermal conductive frame 270. In an embodiment, a portion of the transparent ceramic filler 232 is in contact with the transparent ceramic substrate 240 to accelerate the conduction of heat from the high thermal conductive color conversion layer 230 to the transparent ceramic substrate 240. Since most of the radiation heat is absorbed at the transparent ceramic substrate 240, the radiation heat may be prevented from radiating upward from the transparent ceramic substrate 240 to the polymeric reflective polarizer 290.

Next, the heat received by the polymeric reflective polarizer 290 is removed by the thermal conductive frame 280. As such, the temperature of the polymeric reflective polarizer 290 may be lowered to be less than 100° C., which is the temperature range that the polymeric plastic material may withstand. Therefore, in the present embodiment, in addition to the use of a reflective polarizer with glass substrate, a low-cost polymeric reflective polarizer 290 is also available.

In the present embodiment, by combining the high thermal conductive color conversion layer 230 and the transparent ceramic substrate 240 with the polymeric reflective polarizer 290, and fixing the transparent ceramic substrate 240 and the polymeric reflective polarizer 290 respectively with the two thermal conductive frames 270 and 280, the radiation heat received by the polymeric reflective polarizer 290 is directly conducted to the heat sink 300, so as to form a white LED array package structure 200 having low glare and low surface temperature characteristics.

In summary, the advantages of the present invention are as follows:

1. The heat generated by color conversion of the modified composite phosphor layer itself or the heating phenomenon caused by the blue LED may be directly removed to the heat sink 300 directly via the transparent ceramic substrate 240 on the surface thereof in combination with the thermal conductive frame 270 to decrease the surface temperature, so as to use the low-cost polymeric reflective polarizer 290.

2. The polymeric reflective polarizer 290 also directly removes heat to the heat sink 300 via its own thermal conductive frame 280, reducing surface temperature for extending lifespan.

The foregoing descriptions of the preferred embodiments of the present invention have been provided for the purposes of illustration and explanations. It is not intended to be exclusive or to confine the invention to the precise form or to the disclosed exemplary embodiments. Accordingly, the foregoing descriptions should be regarded as illustrative rather than restrictive. Obviously, many modifications and variations will be apparent to professionals skilled in this art. The embodiments are chosen and described in order to best explain the principles of the invention and its best mode for practical applications, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary to confine the scope defined by the claims to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules on the requirement of an abstract for the purpose of conducting survey on patent documents, and should not be used to interpret or limit the scope or meaning of the claims. Any advantages and benefits described hereto may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light emitting diode array package structure with high thermal conductivity suitable for being mounted on a heat sink, comprising:
a package substrate disposed on the heat sink and including a circuit layer and an insulating layer, the insulating layer being located on the circuit layer;
a light emitting diode array including a plurality of light emitting diode chips arranged in an array form, wherein each of the light emitting diode chips is directly mounted on the insulating layer of the package substrate and electrically connected to the circuit layer;
a high thermal conductive color conversion layer directly dispensed on the light emitting diode array and the package substrate, the high thermal conductive color conversion layer including a transparent optical resin, a phosphor powder and a transparent ceramic filler, wherein the phosphor powder and the transparent ceramic filler are mixed into the transparent optical resin, and a portion of the transparent ceramic filler is in direct contact with the package substrate to form a thermal conduction path; and
a transparent ceramic substrate directly covering and being in contact with an upper surface of the high thermal conductive color conversion layer, and being in contact with another portion of the transparent ceramic filler to form another thermal conduction path.

2. The light emitting diode array package structure with high thermal conductivity according to claim 1, wherein the transparent ceramic filler is in the form of a powder having a particle size of nano-scale, named a nano-scale transparent ceramic filler.

3. The light emitting diode array package structure with high thermal conductivity according to claim 2, wherein the weight percentage of the nano-scale transparent ceramic filler relative to the transparent optical resin is greater than 0% and less than or equal to 10%.

4. The light emitting diode array package structure with high thermal conductivity according to claim 2, wherein the weight percentage of the nano-scale transparent ceramic filler relative to the transparent optical resin is greater than 0% and less than or equal to 20%.

5. The light emitting diode array package structure with high thermal conductivity according to claim 2, wherein the material of both the nano-scale transparent ceramic filler and the transparent ceramic substrate is selected from a group consisting of aluminum nitride, aluminium oxide, magnesium aluminate spinel, aluminum oxynitride, quartz and glass.

6. The light emitting diode array package structure with high thermal conductivity according to claim 5, wherein the material of the nano-scale transparent ceramic filler is the same as that of the transparent ceramic substrate.

7. The light emitting diode array package structure with high thermal conductivity according to claim 1, further comprising:
a first thermal conductive frame connecting a periphery of the transparent ceramic substrate to the heat sink.

8. The light emitting diode array package structure with high thermal conductivity according to claim 1, further comprising:
a reflective polarizer disposed on the transparent ceramic substrate, an air gap being formed between the reflective polarizer and the transparent ceramic substrate; and
a second thermal conductive frame connecting a periphery of the reflective polarizer to the heat sink.

9. The light emitting diode array package structure with high thermal conductivity according to claim 8, wherein the reflective polarizer is selected from one of a reflective polarizer with glass substrate and a reflective polarizer with polymeric substrate.

10. The light emitting diode array package structure with high thermal conductivity according to claim 1, wherein the first thermal conductive frame and the second thermal conductive frame are each fixed to the heat sink with a high thermal conductivity screw.
